(19) United States
(12) Patent Application Publication
(10) Pub. No.: US 2026/0238174 A1
(43) Pub. Date: Aug. 13, 2026

(54) METHODS OF FABRICATING BULK ACOUSTIC WAVE RESONATORS AND FILTERS

(71) Applicant: MACOM Technology Solutions Holdings, Inc., Lowell, MA (US)

(72) Inventors: Renyuan Wang, Windham, NH (US); Andrew M. Carlin, Acton, MA (US)

(21) Appl. No.: 19/451,815

(22) Filed: Jan. 16, 2026

Related U.S. Application Data
(60) Provisional application No. 63/756,855, filed on Feb. 11, 2025.

(51) Int. Cl. H03H 3/02; H03H 9/02; H03H 9/17

(52) U.S. Cl. CPC H03H 3/02; H03H 9/02015; H03H 9/174; H03H 2003/023

(57) ABSTRACT

A method of fabricating a bulk acoustic wave resonator comprises forming a recess in a substrate, forming a sacrificial material in the recess, forming a lower electrode on substrate and the sacrificial material, and forming an alternating polarization piezoelectric film stack that comprises at least two piezoelectric films using a molecular beam epitaxy system without removing the substrate from the molecular beam epitaxy system.

### CROSS-REFERENCE TO RELATED APPLICATION

The present application claims priority under 35 U.S.C. § 119 to U.S. Provisional Patent Application Ser. No. 63/756,855, filed Feb. 11, 2025, the entire content of which is incorporated herein by reference.

### FIELD

The present application relates to resonators and filters and, more particularly, to methods of forming bulk acoustic wave filters that comprise one or more bulk acoustic wave resonators.

### BACKGROUND

Radio frequency (“RF”) bulk acoustic wave filters are widely used in modern wireless communications systems due to their compact size and high performance. As the industry moves toward future generations of wireless protocols, there is increasing demand for compact, high performance filters that can operates beyond the C band frequency range into the low Kᵤ band frequency range. One known type of acoustic wave filter is the thin film bulk acoustic wave filter (“BAW filter”). BAW filters are typically formed by electrically interconnecting a plurality of BAW resonators. Unfortunately, direct scaling the thickness of the thin piezoelectric film of a BAW resonator to operate in the low Kᵤ band frequency range may lead to various detrimental effects.

BAW resonators comprise a suspended thin piezoelectric membrane that is sandwiched between two electrodes. FIG. 1 is a schematic cross-sectional view of a conventional BAW resonator 1. The BAW resonator 1 comprises a substrate 10 that has an air-filled recess 12 in an upper surface thereof. A multi-layer structure is provided on an upper surface of the substrate 10 and suspended above the recess 12. This multi-layer structure comprises a lower electrode 30 that may directly contact the substrate 10 and which may directly overlie the recess 12, a piezoelectric membrane 20 that is formed above the lower electrode 30, and an upper electrode 40 that is formed on an upper surface of the piezoelectric membrane 20. Piezoelectric-to-air interfaces are provided on both major surfaces of the piezoelectric membrane 20. An RF electric field is applied to the piezoelectric film 20 by the opposed electrodes exciting an alternating extension and contraction motion in the thickness direction of the piezoelectric membrane 20 through an inverse-piezoelectric effect. This extension and contraction motion can be viewed as a vertically traveling longitudinal bulk acoustic wave bounded by two “acoustic mirrors” formed by the top and bottom piezoelectric-to-air interfaces, and the piezoelectric membrane 20 resonates at frequencies where the device thickness is a multiple of half of the acoustic wavelengths.

Since the resonant frequency of BAW resonator is proportional to the thickness of its piezoelectric membrane, scaling a BAW resonator that is designed to operate in the 2 GHz frequency range to operate in, for example, the 20 GHz frequency range, requires a proportional reduction (1/f) in the thickness of the piezoelectric membrane. Such scaling leads to a significant reduction in the thickness of the suspended piezoelectric membrane, increasing its susceptibility to rupturing. In addition, the reduction in the thickness of the piezoelectric membrane leads to a proportional increase in capacitance per unit area within the device. To maintain the absolute impedance of the scaled device to interface with a 50 Ohm system (e.g., 50 Ohm input and output transmission lines, a 50 Ohm resistive load, etc.), the area of the active region needs to be proportionally scaled by a factor of 1/f². The reduction in the size of the active region may result in resonator quality factor degradation, as well as linearity and power handling capability degradation.

A known technique for breaking the scaling relationship between resonant frequency and the thickness of the piezoelectric membrane in a BAW resonator is to form the piezoelectric membrane as a stack of piezoelectric films that have periodically inverted polarizations that operate in the high order harmonics of the BAW resonator (referred to herein as an “alternating polarization piezoelectric film stack”). This technique allows up-scaling BAW resonators for operation in higher frequency bands without direct scaling of the physical dimensions of the resonators.

### SUMMARY

Pursuant to some embodiments of the present invention, a method of fabricating a bulk acoustic wave resonator is provided in which a first metal-polar piezoelectric film is formed on a substrate. A first polarization inversion interlayer is then formed on the first metal-polar piezoelectric film via molecular beam epitaxy. A first N-polar nucleation layer is formed on the first polarization inversion interlayer. Finally, a first N-polar piezoelectric film is formed on the first N-polar nucleation layer via molecular beam epitaxy.

In some embodiments, the method may further comprise forming a second polarization inversion interlayer on the first N-polar piezoelectric film via molecular beam epitaxy and then forming a second metal-polar piezoelectric film on the second polarization inversion interlayer via molecular beam epitaxy.

In some embodiments, the method may further comprise forming a recess in the substrate and forming a sacrificial material in the recess prior to forming the first metal-polar piezoelectric film, wherein the first metal-polar piezoelectric film is also formed on the sacrificial material. In some embodiments, the first metal-polar piezoelectric film comprises a first metal-polar scandium aluminum nitride film. In some embodiments, the first metal-polar piezoelectric film may be formed by molecular beam epitaxy. In some embodiments, the first metal-polar piezoelectric film may be formed in a nitrogen-rich growth condition.

In some embodiments, the first polarization inversion interlayer comprises a first interlayer that comprises silicon. In some example embodiments, the first interlayer that comprises silicon may be a beta-phase silicon nitride interlayer. In other example embodiments, the first interlayer that comprises silicon may be a single-crystalline epitaxial grown silicon interlayer. Other silicon-containing interlayers may be used. In some embodiments, the first N-polar nucleation layer comprises an N-polar aluminum nitride nucleation layer that is formed by an alumination process.

In some embodiments, the first polarization inversion interlayer comprises silicon. In some embodiments, the first N-polar nucleation layer comprises an N-polar aluminum nitride nucleation layer that is formed by molecular beam epitaxy in an aluminum rich growth condition, although embodiments of the present invention are not limited thereto.

In some embodiments, the first N-polar piezoelectric film comprises a first N-polar scandium aluminum nitride film. In some embodiments, the first N-polar scandium aluminum nitride film is grown in a nitrogen rich growth condition.

In some embodiments, the first N-polar nucleation layer comprises a first N-polar aluminum nitride nucleation layer and the first N-polar piezoelectric film comprises a first N-polar scandium aluminum nitride film. In some embodiments, the method may further comprise performing an anneal to burn-off excess aluminum after forming the N-polar aluminum nitride nucleation layer and before forming the first N-polar scandium aluminum nitride film. In some embodiments, the method may additionally comprise performing an anneal after forming the first N-polar aluminum nitride nucleation layer and before forming the first N-polar scandium aluminum nitride film.

In some embodiments, forming the second polarization inversion interlayer on the first N-polar piezoelectric film via molecular beam epitaxy comprises forming a second polarization inversion interlayer that comprises silicon on the first N-polar piezoelectric film via molecular beam epitaxy. In some embodiments, forming a second metal-polar piezoelectric film on the second polarization inversion interlayer via molecular beam epitaxy comprises forming a metal-polar scandium aluminum nitride film via molecular beam epitaxy.

Pursuant to further embodiments of the present invention, a method of fabricating a bulk acoustic wave resonator is provided in which a recess is formed in a substrate. A sacrificial material is formed in the recess. A lower electrode is formed on substrate and the sacrificial material. Then, an alternating polarization piezoelectric film stack that comprises at least two piezoelectric films is formed on the lower electrode using a molecular beam epitaxy system without removing the substrate from the molecular beam epitaxy system.

In some embodiments, the at least two piezoelectric films a first metal-polar piezoelectric film and a first N-polar piezoelectric film. In some embodiments, forming a second metal-polar piezoelectric film on the second polarization inversion interlayer via molecular beam epitaxy comprises forming a metal-polar scandium aluminum nitride via molecular beam epitaxy.

In some embodiments, forming the alternating polarization piezoelectric film stack that comprises at least two piezoelectric films comprises forming an interlayer between a first of the at least two piezoelectric films and a second of the at least two piezoelectric films that is formed after the first of the at least two piezoelectric films is formed. In some embodiments, forming the alternating polarization piezoelectric film stack that comprises at least two piezoelectric films further comprises forming a nucleation layer on the first of the at least two piezoelectric films before forming the second of the at least two piezoelectric films. In some embodiments, the first interlayer comprises silicon. In some embodiments, the first interlayer comprises a beta-phase silicon nitride interlayer. In some embodiments, the first nucleation layer comprises an N-polar aluminum nitride nucleation layer.

In some embodiments, the first interlayer is a silicon interlayer. In some embodiments, the first nucleation layer comprises an N-polar aluminum nitride nucleation layer that is formed by molecular beam epitaxy. The N-polar aluminum nitride nucleation layer may optionally be formed in an aluminum rich growth condition. In some embodiments, the method may further comprise forming a first metal-polar piezoelectric film on the lower electrode via molecular beam epitaxy.

In some embodiments, the first of the at least two piezoelectric films comprises a first metal-polar scandium aluminum nitride film and a second of the at least two piezoelectric films comprises a first N-polar scandium aluminum nitride film.

Pursuant to additional embodiments of the present invention, bulk acoustic wave resonators are provided that comprise a substrate having a recess in an upper surface thereof, a lower electrode on the upper surface of the substrate, the lower electrode extending over the recess, an alternating polarization piezoelectric film stack that comprises a first metal-polar piezoelectric film, a first polarization inversion interlayer, and a first N-polar piezoelectric film on the lower electrode, and an upper electrode on the alternating polarization piezoelectric film stack.

The first polarization inversion interlayer may include silicon

In some embodiments, the first metal-polar piezoelectric film, the first polarization inversion interlayer, and the first N-polar piezoelectric film are sequentially stacked on the lower electrode, and the alternating polarization piezoelectric film stack further comprises a second polarization inversion interlayer on the first N-polar piezoelectric film and a second metal-polar piezoelectric film on the second polarization inversion interlayer. In other embodiments, the first N-polar piezoelectric film, the first polarization inversion interlayer, and the first metal-polar piezoelectric film are sequentially stacked on the lower electrode, and the alternating polarization piezoelectric film stack further comprises a second polarization inversion interlayer on the first metal-polar piezoelectric film and a second N-polar piezoelectric film on the second polarization inversion interlayer.

Pursuant to yet additional embodiments of the present invention, a method of fabricating a bulk acoustic wave resonator is provided in which a first piezoelectric film is formed on a substrate, the first piezoelectric film having a first polarization. A first polarization inversion interlayer is formed on the first piezoelectric film via molecular beam epitaxy. A first nucleation layer is formed on the first polarization inversion interlayer. A second piezoelectric film is formed on the first nucleation layer via molecular beam epitaxy, the second piezoelectric film having a second polarization that is different than the first polarization. A second polarization inversion interlayer is then formed on the second piezoelectric film via molecular beam epitaxy, and a third piezoelectric film is formed on the second polarization inversion interlayer via molecular beam epitaxy, the third piezoelectric film having the first polarization

In some embodiments, the method may further comprise forming a recess in the substrate and forming a sacrificial material in the recess prior to forming the first piezoelectric film. The first piezoelectric film may also be formed on the sacrificial material.

In some embodiments, the first polarization is a metal-polar polarization and the second polarization is an N-polar polarization. In other embodiments, first polarization is an N-polar polarization and the second polarization is a metal-polar polarization.

### BRIEF DESCRIPTION OF THE DRAWINGS

FIG. 1 is a schematic cross-sectional view of a conventional BAW resonator.

FIGS. 2A and 2B are schematic cross-sectional views that illustrate the direction of mechanical deformation in a single film piezoelectric film (FIG. 2A) and in an alternating polarization piezoelectric film stack (FIG. 2B) and how the use of an alternating polarization piezoelectric film stack allows for higher frequency operation without directly scaling the size of the device (FIG. 2B).

FIG. 3 is a schematic diagram with an embedded graph that shows the frequency response of a BAW resonator having a single film piezoelectric film as compared to the frequency response of a BAW resonator having an alternating polarization piezoelectric film stack.

FIG. 4 is a flow chart illustrating operations of a method of forming a BAW resonator according to certain embodiments of the present invention.

FIGS. 5A-5I are schematic cross-sectional views that illustrate a method of forming a BAW resonator according to embodiments of the present invention.

FIG. 6 is a flow chart illustrating operations of a method of forming a BAW resonator according to further embodiments of the present invention.

FIGS. 7A-7F are schematic cross-sectional diagrams that illustrate the method of forming the BAW resonator of FIG. 6.

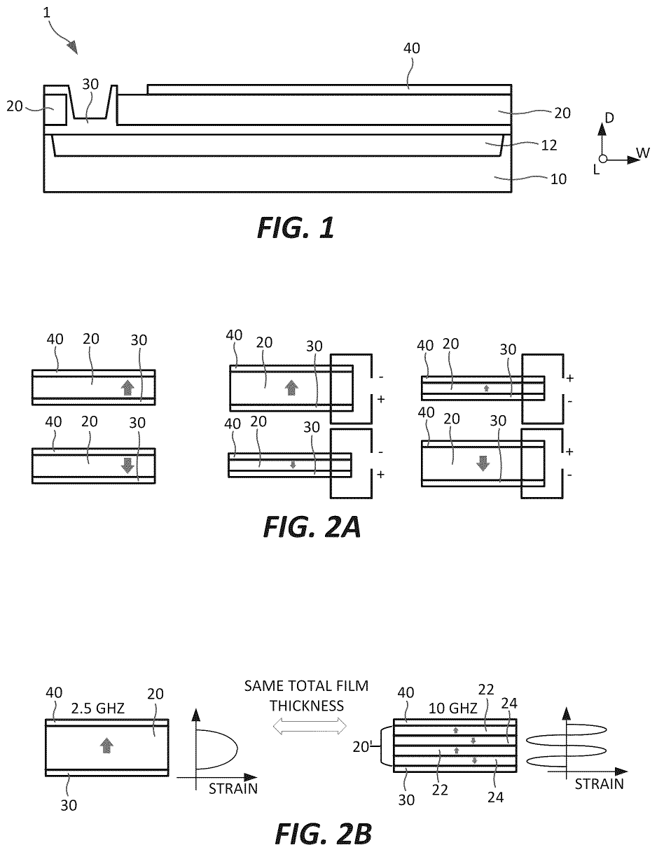

### DETAILED DESCRIPTION

The concept of operating in high order harmonics of a BAW resonator using an alternating polarization piezoelectric film stack can be understood from FIGS. 2A-2B. As shown in FIG. 2A, in a BAW resonator that has a single piezoelectric film 20 (and hence a single polarization) that is in between a lower electrode 30 and an upper electrode 40, the extension and contraction motion of the piezoelectric film 20 is either in-phase or out-of-phase (depending on the polarization of the piezoelectric film 20, where the polarization is indicated by the bold arrows superimposed on the piezoelectric films 20) with the RF electric field at resonance. Thus, the direction of mechanical deformation is a function of the polarization of the piezoelectric material. As shown in FIG. 2B, in a BAW resonator having a stacked piezoelectric film structure 20′ that comprises an alternating stack of piezoelectric films 22, 24 having different polarizations, the piezoelectric films 22, 24 with different polarizations move out of phase so that the entire piezoelectric film structure 20′ vibrates at the n^{th} harmonic of the stacked piezoelectric film structure 20′, where n is the number of piezoelectric films 22, 24 with alternating polarizations. This breaks the direct scaling between the total thickness of the piezoelectric membrane and the resonant frequency thereof, thereby allowing a BAW resonator to operate at much higher frequencies while maintaining a similar total thickness of the piezoelectric film structure 20′ that is the same as that of a lower frequency BAW resonator.

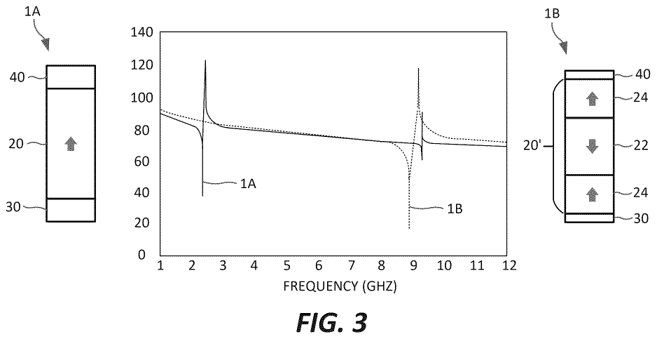

FIG. 3 is a schematic diagram that includes a graph that shows the results of a finite element simulation that compares the frequency response of a conventional BAW resonator 1A (shown on the left side of FIG. 3) that has a single aluminum nitride 1.08 micron thick piezoelectric film 20 that is interposed in between a lower electrode 30 and an upper electrode 40 that each have a thickness of 0.24 microns and a BAW resonator 1B having a three film alternating polarization piezoelectric film structure 20′ (shown on the right side of FIG. 3) in which a first polarization piezoelectric film 22 is interposed in between a pair of second polarization piezoelectric films 24, and the alternating polarization piezoelectric film structure 20′ is interposed in between a lower electrode 30 and an upper electrode 40. The first polarization piezoelectric film 22 is a 0.6 micron thick aluminum nitride film 22 and the second polarization piezoelectric films 24 are each 0.4 micron thick aluminum nitride films. The metal electrodes in BAW resonator 1B are each 0.2 microns thick. The total thickness of the piezoelectric membrane 20 included in BAW resonator 1A and the three film alternating polarization piezoelectric film structure 20′ included in BAW resonator 1B in the simulations are similar (1.56 microns and 1.6 microns, respectively). While the primary resonance of the conventional BAW resonator 1A is at about 2.3 GHz, the BAW resonator 1B having an alternating polarization piezoelectric film stack 20′ is resonant at about 8.9 GHz. Inspection of the mode profile shows that the conventional BAW resonator 1A resonates at the fundamental resonance, while the BAW resonator 1B having a three layer alternating polarization piezoelectric film stack 20′ is resonant at the third order harmonic. In addition, the conventional BAW resonator 1A exhibits a weak resonance at the third order harmonic at the same frequency as the resonant frequency of the BAW resonator 1B having the alternating piezoelectric polarization stack 20′. It is worth noting that the frequency of the third order harmonic is not exactly three times of the fundamental resonance, because the alternating piezoelectric polarization stack 20′ also includes metal electrodes 30, 40 which exhibit a different acoustic velocity and acoustic impedance than the alternating piezoelectric polarization stack 20′. Thus, as shown in FIGS. 2A-2B and 3, the use of an alternating polarization piezoelectric film stack 20′ as the piezoelectric membrane allows scaling the resonant frequency of a BAW resonator without directly scaling the thickness of the piezoelectric film. The use of piezoelectric membranes that are implemented as alternating polarization piezoelectric film stacks also enables scaling the device thickness and size for higher power handling capabilities. For example, a BAW resonator that was configured for operation at 5 GHz that included a single piezoelectric film having a thickness T1 could be replaced using the techniques disclosed herein with a BAW resonator that was configured for operation at 5 GHz that included an alternating polarization piezoelectric film stack could have a thickness of n*T1, where “n” is the number of piezoelectric films in the stack. This will allow operation at much higher power levels and improved linearity.

BAW resonators having piezoelectric membranes that comprise an alternating polarization piezoelectric film stack are known in the art. One challenge in fabricating a BAW resonator that has a piezoelectric membrane that comprises a stack of piezoelectric films (e.g., scandium aluminum nitride films) having alternating polarization piezoelectric films is ensuring that the layers in the stack have well-controlled polarization alignment, appropriate thicknesses, proper compositions, good crystal quality and the like. A known technique for fabricating a BAW resonator that has a piezoelectric membrane that comprises an alternating polarization piezoelectric film stack is to form piezoelectric films having alternating polarizations using two different epitaxy tools, such as a metal organic chemical vapor deposition (“MOCVD”) system and a sputtering tool. With this technique, the device is moved in between the two tools in alternating fashion, with each tool used to form the next piezoelectric film of the multi-film piezoelectric membrane. Unfortunately, the long time periods required to ramp up and ramp down the growth temperature in the tools may significantly increase the costs associated with this fabrication technique.

Pursuant to embodiments of the present invention, cost-efficient methods of forming high quality BAW resonators that operate in high frequency ranges (e.g., above 6 GHz) are provided. The BAW resonators formed by these methods have piezoelectric membranes that comprise an alternating polarization piezoelectric film stack, and the alternating polarization piezoelectric film stack is formed using a single tool in a single process run. This technique may be used to form a multi-layer piezoelectric membrane (e.g., a multi-layer scandium aluminum nitride piezoelectric membrane) that has any desired number of alternating polarization films, with the only constraints being growth rate and limits on the total thickness of the piezoelectric membrane. In example embodiments, these alternating polarization piezoelectric film stacks are formed using a multi-deposition step molecular beam epitaxy (“MBE”) process.

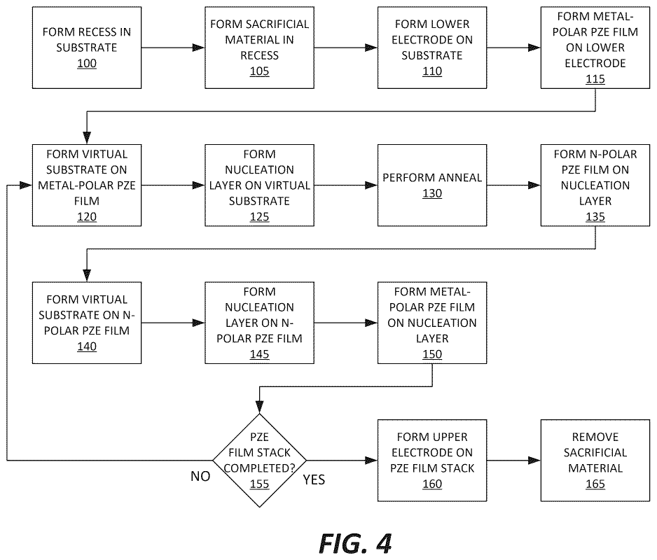

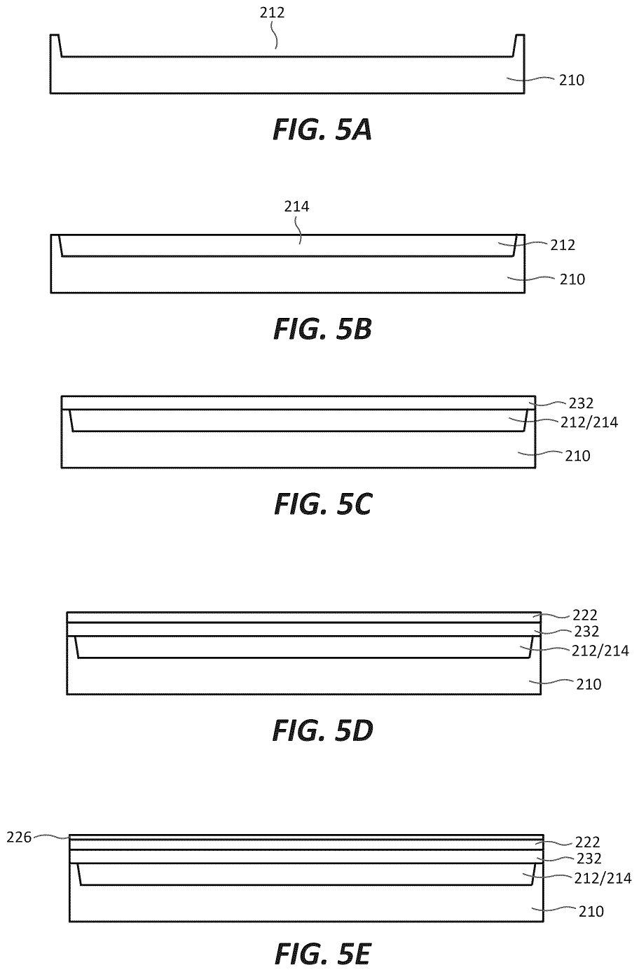

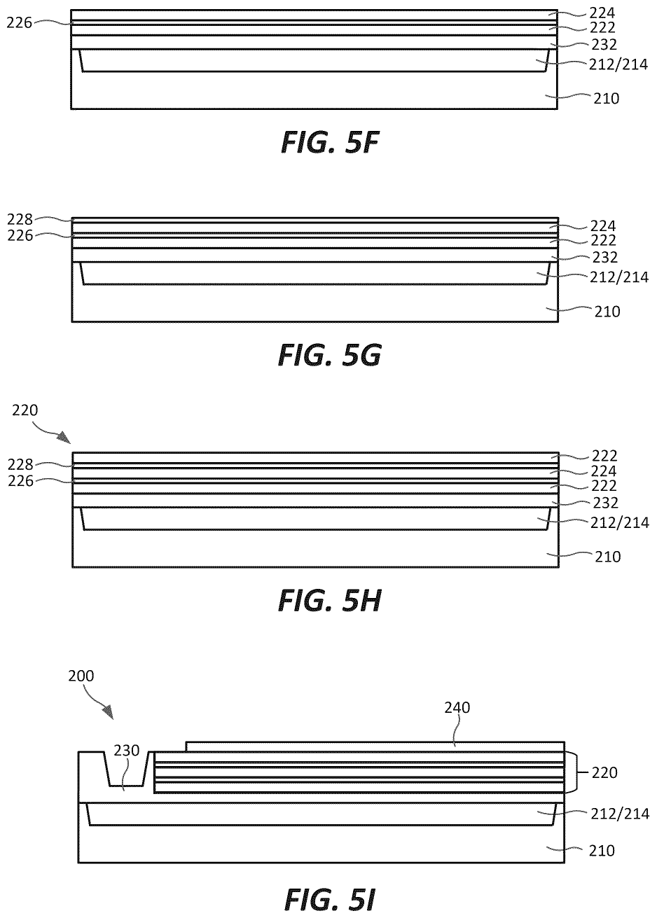

FIG. 4 is a flow chart illustrating operations of a method of forming a BAW resonator 200 according to certain embodiments of the present invention. FIGS. 5A-5I are schematic cross-sectional diagrams that illustrate the method of forming a BAW resonator 200 of FIG. 4.

As shown in FIGS. 4 and 5A, operations may begin with a recess 212 being formed in a substrate 210 (Block 100). The substrate 210 may comprise, for example, a high resistivity silicon substrate. The recess 212 may have a predetermined shape and/or size. The recess 212 may also be referred to as a release bathtub. While the discussion below will discuss a device in which a single recess 212 is formed, it will be appreciated that typically multiple recesses 212 will be formed so that multiple BAW resonators 200 may be formed on the substrate 210 to provide a BAW filter having desired characteristics.

Next, as shown in FIGS. 4 and 5B, a sacrificial material 214 is formed in the recess 212 (Block 105). The sacrificial material 214 may fill the recess 212.

Referring to FIGS. 4 and 5C, next, a preliminary lower electrode 232 is formed on the sacrificial material 214 and/or on the substrate 210 (Block 110). The preliminary lower electrode 232 may be formed directly on an upper surface of the sacrificial material 214 and/or directly on an upper surface of the substrate 210. The preliminary lower electrode 232 may comprise any suitable metal, with molybdenum or tungsten being good options as they are both stable at the MBE growth temperatures for scandium aluminum nitride and both metals can readily be formed by sputtering. The preliminary lower electrode 232 may be formed by first forming an aluminum nitride seed layer (e.g., by sputtering) on the sacrificial material 214 and the substrate 210, and then forming the preliminary lower electrode 232 on the aluminum nitride seed layer. The aluminum nitride seed layer promotes (110) oriented molybdenum growth, where the molybdenum tends to be polycrystalline with in-plane rotated (120°) (110) crystal domains aligned with an underlying hexagonal structure.

Next, as shown in FIGS. 4 and 5D, a first metal-polar piezoelectric film 222 such as, for example, a metal-polar scandium aluminum nitride film 222, is formed on the preliminary lower electrode 232 via MBE. (Block 115). The metal-polar scandium aluminum nitride film 222 may, for example, be formed directly on an upper surface of the preliminary lower electrode 232. The first metal-polar piezoelectric film 222 may be formed in a nitrogen-rich growth condition. Forming the first metal-polar piezoelectric film 222 in the nitrogen-rich growth condition may suppress phase separation and/or multi-phase growth of scandium aluminum nitride.

Referring to FIGS. 4 and 5E, next, a first polarization inversion interlayer 226 may be formed on the first metal-polar piezoelectric film 222 (Block 120). The first polarization inversion interlayer 226 may, for example, be formed directly on an upper surface of the first metal-polar piezoelectric film 222. The first polarization inversion interlayer 226 may comprise silicon. The first polarization inversion interlayer 226 may be a metal-to-N-polar polarization inversion interlayer 226. In some embodiments, the first polarization inversion interlayer 226 may be a silicon interlayer that is formed via MBE. In such embodiments, the silicon interlayer 226 may be thick enough to exhibit a 7×7 reconstruction from reflection high-energy electron diffraction to facilitate growth of a subsequent N-polar piezoelectric film. As the growth of the subsequent N-polar piezoelectric film may have an initial aluminum rich growth condition, the silicon interlayer 226 may have a sufficient thickness to tolerate the loss of silicon through aluminum-silicon eutectic formation. Herein, the term “aluminum-rich” refers to a ratio of aluminum to active nitrogen, at the growth surface, which is greater than 1 (commonly referred to as metal-rich nitride growth). On the other hand, it also may be desirable to limit the thickness of the first polarization inversion interlayer 226 to be greater than, but close to, the thickness that is necessary to achieve the desired polarity reversal. The first polarization inversion interlayer 226 acts as virtual substrate that is formed on the first metal-polar piezoelectric film 222.

Still referring to FIG. 4, next, a first nucleation layer (not shown as it may be very thin) may optionally be grown on the first polarization inversion interlayer 226 (Block 125). The nucleation layer, if provided, may be formed directly on an upper surface of the first polarization inversion interlayer 226. The nucleation layer may comprise a thin N-polar aluminum nitride nucleation layer, and may be grown by MBE under aluminum rich conditions. During this growth, an aluminum-silicon eutectic layer is formed and floats on top of the growth front. Next, a high temperature anneal may optionally be performed to burn-off the excess aluminum to prevent the formation of AlSiN from the Al-Si eutectic during subsequent growth which interrupts N-polar growth (Block 130).

Next, as shown in FIGS. 4 and 5F, a first N-polar piezoelectric film 224 is grown on the N-polar aluminum nitride nucleation layer (Block 135). The first N-polar piezoelectric film 224 may, for example, be grown directly on an upper surface of the N-polar aluminum nitride nucleation layer. The first N-polar piezoelectric film 224 may be a scandium aluminum nitride film, and may be formed by MBE. The first N-polar piezoelectric film 224 may be grown under nitrogen rich growth conditions. Herein, the term “nitrogen-rich” refers to a ratio of active nitrogen to aluminum, at the growth surface, which is greater than 1.

Referring to FIGS. 4 and 5G, next, a second polarization inversion interlayer 228 is formed on the first N-polar piezoelectric film 224 (Block 140). The second polarization inversion interlayer 228 may, for example, be formed directly on an upper surface of the first N-polar piezoelectric film 224. The second polarization inversion interlayer 228 may be, for example, an aluminum silicon nitride interlayer. In other embodiments, the second polarization inversion interlayer 228 may be an aluminum oxide interlayer. The second polarization inversion interlayer 228 may interrupt the N-polar stacking. The second polarization inversion interlayer 228 may be an N-polar-to-metal polarization inversion interlayer 228 that changes the polarization from N-polar to metal-polar. The second polarization inversion interlayer 228 acts as virtual substrate that is formed on the first N-polar piezoelectric film 224. One method of forming an aluminum oxide interlayer is to oxidize the surface of the N-polar piezoelectric film 224 via an oxygen plasma process in the MBE growth chamber or by moving the wafer into a separate chamber attached to the MBE growth chamber and heating the wafer in an oxygen environment (e.g., a mixture of oxygen and nitrogen gases).

Still referring to FIG. 4, next, a second nucleation layer (not shown as it may be very thin) is formed on the second polarization inversion interlayer 228 (Block 145). The second nucleation layer may be formed directly on an upper surface of the second polarization inversion interlayer 228. The second nucleation layer may comprise, for example, a thin metal-polar aluminum nitride nucleation layer, which may be grown by MBE under nitrogen rich conditions.

Referring to FIGS. 4 and 5H, next, a second metal-polar piezoelectric film 222 may be formed by MBE on the second nucleation layer. (Block 150). The second metal-polar piezoelectric film 222 may, for example, be formed directly on an upper surface of the second nucleation layer. The second metal-polar piezoelectric film 222 may be a scandium aluminum nitride film, and may be grown by further introducing scandium into the MBE system to continue epitaxy of metal-polar scandium aluminum nitride.

Referring to FIG. 4, next, a determination is made as to whether an alternating polarization piezoelectric film stack 220 that comprises at least one metal-polar piezoelectric film 222 and at least one N-polar piezoelectric film 224 has been completed (Block 155). If not, operations return to Block 120 so that the operations of Blocks 120 through 150 can be repeated to continue the growth cycle until a desired number of piezoelectric films 222, 224 have been formed in the alternating piezoelectric film stack 220.

Referring to FIGS. 4 and 5I, once a desired number of piezoelectric films 222, 224 have been formed, operations continue with an upper electrode 240 being formed on the upper surface of the alternating polarization piezoelectric film stack 220 (Block 160). The upper electrode 240 may comprise any suitable metal, such as molybdenum or tungsten. The upper electrode 240 may be formed, for example, by sputtering. The alternating polarization piezoelectric film stack 220 may also be etched to expose the preliminary lower electrode 232, and additional metal may be deposited in the opening to convert the preliminary lower electrode 232 into a lower electrode 230. It will be appreciated that in other embodiments the lower electrode 230 may be formed in the process shown in FIG. 5B as opposed to a preliminary lower electrode, and the alternating polarization piezoelectric film stack 220 may merely be etched in the process of FIG. 5I to expose the lower electrode 230 and allow electrical contact to be made thereto.

In a subsequent step, the sacrificial material 214 that is in the recess 212 is selectively removed so that the alternating polarization piezoelectric film stack 220 with the lower and upper electrodes 230, 240 on opposed surfaces thereof is suspended above the release bathtub. The sacrificial material 214 may comprise, for example, silicon dioxide (SiO₂) as silicon dioxide has high temperature stability and otherwise is very compatible with MBE processing.

As discussed above with respect to the operation of Block 120 of FIG. 4, the first polarization inversion interlayer may comprise a single-crystalline epitaxial grown silicon interlayer in some embodiments that is formed by MBE. In other embodiments, the first polarization inversion interlayer may be a beta-phase silicon nitride layer that is deposited in-situ by MBE. In such embodiments, an alumination process may then be used to form an N-polar AlN nucleation layer.

While a method is described above in which a BAW resonator having a three-layer alternating polarization piezoelectric film stack is formed, it will be appreciated that embodiments of the present invention are not limited thereto. In other embodiments, the above-described method may be continued to provide an alternating polarization piezoelectric film stack having more than three layers, while in still other embodiments, the alternating polarization piezoelectric film stack may be formed to have only two layers.

Pursuant to further embodiments of the present invention, BAW resonators are provided such as BAW resonator 200 that include an alternating polarization piezoelectric film stack. In particular, referring to FIG. 5I, the BAW resonator 200 includes a substrate 210 having a recess 212 in an upper surface thereof. A lower electrode 230 is provided on the upper surface of the substrate 210. The lower electrode 230 may extend over the recess 212. An alternating polarization piezoelectric film stack 220 is formed on the lower electrode 230. The alternating polarization piezoelectric film stack 220 may comprise at least a first metal-polar piezoelectric film 222, a first polarization inversion interlayer 226, 228, and a first N-polar piezoelectric film 224. An upper electrode 240 is provided on the alternating polarization piezoelectric film stack 220. The first polarization inversion interlayer 226, 228 may comprise silicon.

In some embodiments, the first metal-polar piezoelectric film 222, the first polarization inversion interlayer 226, and the first N-polar piezoelectric film 224 are sequentially stacked on the lower electrode 230, as shown in FIG. 5I. In such embodiments, the alternating polarization piezoelectric film stack 220 may optionally further comprise a second polarization inversion interlayer 228 on the first N-polar piezoelectric film 224 and a second metal-polar piezoelectric film 222 on the second polarization inversion interlayer 228. In other embodiments, the first N-polar piezoelectric film 224, the first polarization inversion interlayer 228, and the first metal-polar piezoelectric film 222 are sequentially stacked on the lower electrode 230. In such embodiments, the alternating polarization piezoelectric film stack 220 may optionally further comprise a second polarization inversion interlayer 226 on the first metal-polar piezoelectric film 222 and a second N-polar piezoelectric film 224 on the second polarization inversion interlayer 226.

It will be appreciated that many modifications may be made to the above described manufacturing process without departing from the scope of the present invention. For example, the piezoelectric films that are used to form the alternating polarization piezoelectric film stack may be different than the example piezoelectric films discussed above. It will also be appreciated that any suitable materials may be used to form the lower and upper electrodes, including multi-layer metallization stacks. It will likewise be understood that different materials may be used to form the virtual substrates and/or the nucleation layers.

Pursuant to further embodiments of the present invention, methods of fabricating BAW resonators that include a piezoelectric membrane that comprises an alternating polarization piezoelectric film stack are provided in which a first N-polar piezoelectric film is first formed on a substrate as opposed to a metal-polar piezoelectric film. A first polarization inversion interlayer is then formed on the first N-polar piezoelectric film via molecular beam epitaxy. A first metal-polar nucleation layer is formed on the first polarization inversion interlayer. Finally, a first metal-polar piezoelectric film is formed on the first metal-polar nucleation layer via molecular beam epitaxy.

One potential difficulty in forming a piezoelectric membrane that comprises an alternating polarization piezoelectric film stack that has a first N-polar piezoelectric film as the lowermost layer in the stack is that when a piezoelectric film is grown via MBE on a metal electrode (e.g., the lower electrode), the growth of the piezoelectric film tends to be metal-polar. To form an N-polar piezoelectric film as the first layer on a metal electrode, a thin layer of N-polar AlN may be sputtered on the metal electrode as a seed layer. The wafer having this AlN seed layer formed on the metal electrode may then be moved into an MBE growth chamber. Since the wafer having the AlN seed layer formed on the metal electrode is exposed to air during the sputtering process, the exposed upper surface of the AlN seed layer may tend to oxidize. If a piezoelectric film is grown by MBE on an oxidized AlN surface, the growth tends to be metal-polar. To promote N-polar growth instead, an in-situ cleaning process may be performed after the wafer having the AlN seed layer formed on the metal electrode is loaded into the MBE growth chamber. This in-situ cleaning process may be used to remove oxidized surface of the AlN seed layer in order to expose the N-polar material. Thereafter, the first N-polar piezoelectric film may be grown by MBE on the N-polar AlN seed layer. The in-situ cleaning process can be achieved by depositing pure aluminum on the oxidized surface and then heating the wafer to very high temperatures to remove the trace amount of oxygen as well as excess aluminum. This process may be repeated as many times as necessary until most or all of the surface oxide material has been removed.

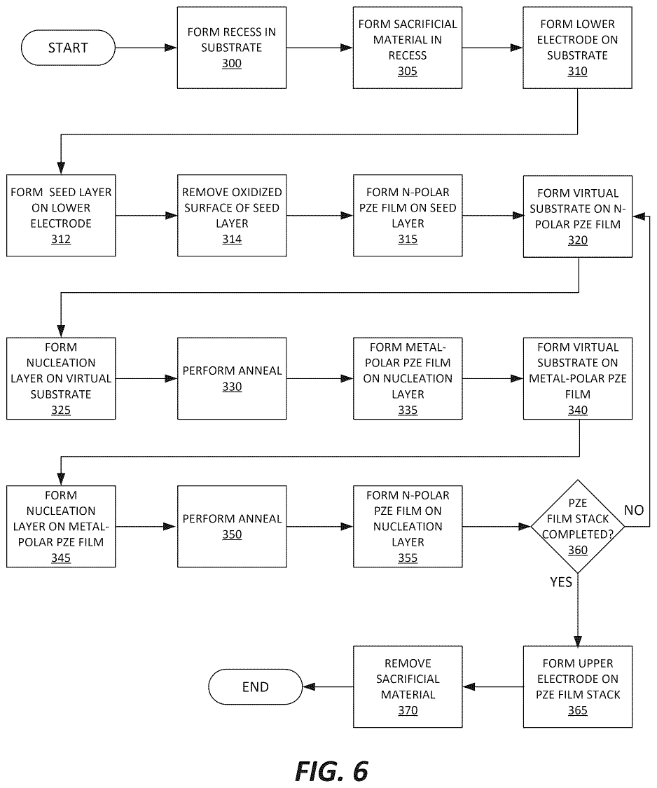

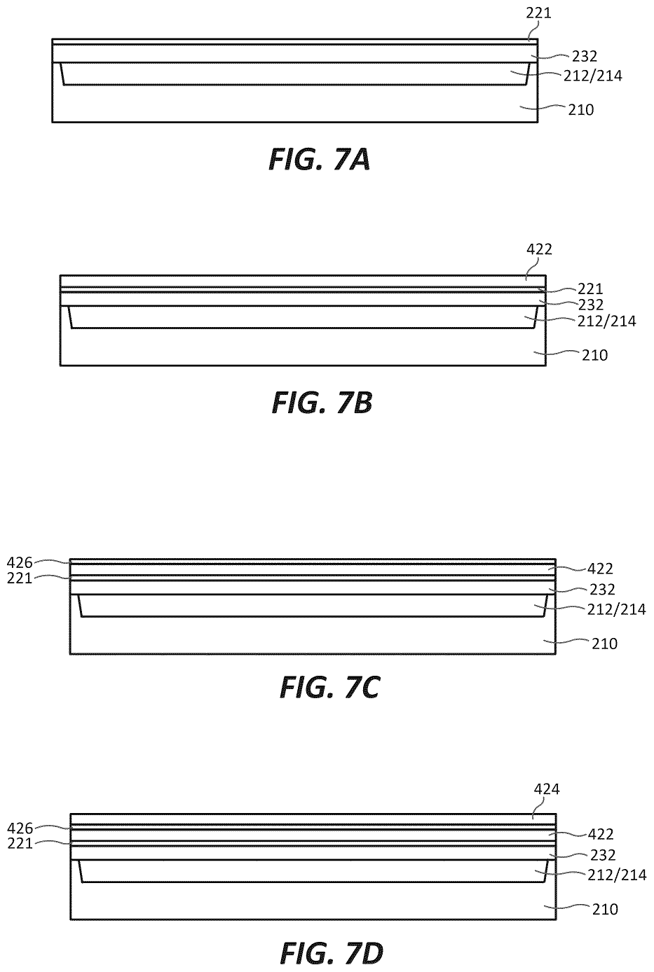

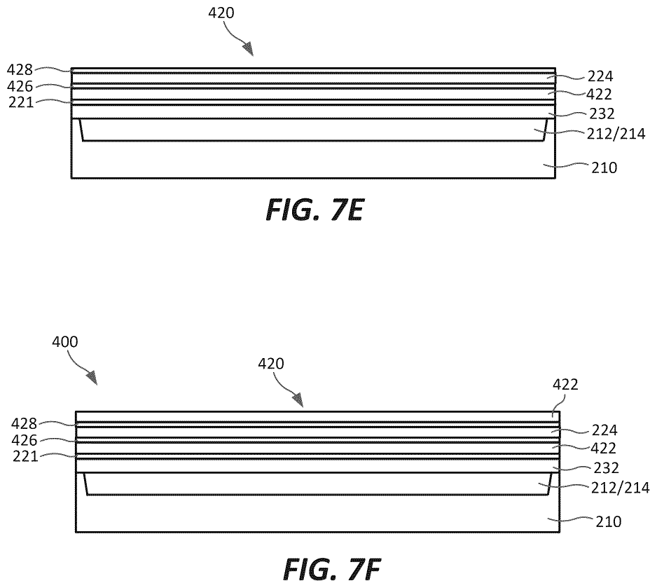

FIG. 6 is a flow chart illustrating operations of a method of forming a BAW resonator 400 according to further embodiments of the present invention. FIGS. 7A-7F are schematic cross-sectional diagrams that illustrate the method of forming the BAW resonator 400 of FIG. 6.

As shown in FIG. 6, operations may begin with a recess 212 being formed in a substrate 210 (Block 300), and then a sacrificial material 214 is formed in the recess 212 (Block 305). Next, a preliminary lower electrode 232 is formed on the sacrificial material 214 and/or on the substrate 210 (Block 310). The steps of Blocks 300, 305 and 310 of FIG. 6 may be identical to the corresponding steps of Blocks 100, 105 and 110 of FIG. 4, and hence further description of these steps will be omitted. FIGS. 5A-5C schematically illustrate the device after each respective one of these steps is performed.

Next, as shown in FIGS. 6 and 7A, a thin layer of N-polar AlN may be sputtered on the preliminary metal electrode 232 as an AlN seed layer 221 (Block 312). The substrate 210 having this AlN seed layer 221 formed on the preliminary metal electrode 232 may then be moved into an MBE growth chamber. Since the AlN seed layer 221 is exposed to air during the sputtering process, the exposed upper surface of the AlN seed layer 221 may oxidize. As discussed above, an in-situ cleaning process may be performed after the substrate 210 having the AlN seed layer 221 thereon is loaded into the MBE growth chamber to remove any oxidized AlN from the surface of the AlN seed layer 221 in order to expose the N-polar AlN material (Block 314).

Next, as shown in FIGS. 6 and 7B, a first N-polar piezoelectric film 422 such as, for example, an N-polar scandium aluminum nitride film 422, is formed on the AlN seed layer 221 via MBE. (Block 315). The first N-polar piezoelectric film 422 may be formed in a nitrogen-rich growth condition in some embodiments.

Referring to FIGS. 6 and 7C, next, a first polarization inversion interlayer 426 may be formed on the first N-polar piezoelectric film 422 (Block 320). The first polarization inversion interlayer 426 may, for example, be formed directly on an upper surface of the first N-polar piezoelectric film 422. The first polarization inversion interlayer 426 may comprise an aluminum silicon nitride interlayer. The first polarization inversion interlayer 426 may be an N-to-metal-polar polarization inversion interlayer 426. In some embodiments, the first polarization inversion interlayer 426 may be formed via MBE. The first polarization inversion interlayer 426 acts as virtual substrate that is formed on the first N-polar piezoelectric film 422.

Still referring to FIG. 6, next, a first nucleation layer (not shown as it may be very thin) may optionally be grown on the first polarization inversion interlayer 426 (Block 325). The nucleation layer, if provided, may be formed directly on an upper surface of the first polarization inversion interlayer 426. The nucleation layer may comprise a thin metal-polar aluminum nitride nucleation layer, and may be grown by MBE under aluminum rich conditions. Next, a high temperature anneal may optionally be performed (Block 330).

Next, as shown in FIGS. 6 and 7D, a first metal-polar piezoelectric film 424 is grown on the metal-polar aluminum nitride nucleation layer (Block 335). The first metal-polar piezoelectric film 424 may, for example, be grown directly on an upper surface of the metal-polar aluminum nitride nucleation layer. The first metal-polar piezoelectric film 424 may be a scandium aluminum nitride film, and may be formed by MBE. The first metal-polar piezoelectric film 424 may be grown under nitrogen rich growth conditions.

Referring to FIGS. 6 and 7E, next, a second polarization inversion interlayer 428 is formed on the first metal-polar piezoelectric film 424 (Block 340). The second polarization inversion interlayer 428 may, for example, be formed directly on an upper surface of the first metal-polar piezoelectric film 424. The second polarization inversion interlayer 428 may be, for example, a silicon interlayer. The second polarization inversion interlayer 428 may interrupt the metal-polar stacking. The second polarization inversion interlayer 428 may be a metal-polar-to-N polarization inversion interlayer 428 that changes the polarization from metal-polar to N-polar. The second polarization inversion interlayer 428 acts as virtual substrate that is formed on the first metal-polar piezoelectric film 424.

Still referring to FIG. 6, next, a second nucleation layer (not shown as it may be very thin) is formed on the second polarization inversion interlayer 428 (Block 345). The second nucleation layer may be formed directly on an upper surface of the second polarization inversion interlayer 428. The second nucleation layer may comprise, for example, a thin N-polar aluminum nitride nucleation layer, which may be grown by MBE under metal rich conditions. Next, a high temperature anneal may be performed to burn off excess metal (e.g., aluminum) (Block 350).

Referring to FIGS. 6 and 7F, next, a second N-polar piezoelectric film 422 may be formed by MBE on the second nucleation layer. (Block 355). The second N-polar piezoelectric film 422 may, for example, be formed directly on an upper surface of the second nucleation layer. The second N-polar piezoelectric film 422 may be a scandium aluminum nitride film, and may be grown by further introducing scandium into the MBE system to continue epitaxy of N-polar scandium aluminum nitride.

Referring to FIG. 6, next, a determination is made as to whether an alternating polarization piezoelectric film stack 420 that comprises at least one N-polar piezoelectric film 422 and at least one metal-polar piezoelectric film 424 has been completed (Block 360). If not, operations return to Block 320 so that the operations of Blocks 320 through 355 can be repeated to continue the growth cycle until a desired number of piezoelectric films 422, 424 have been formed in the alternating piezoelectric film stack 420. Once a desired number of piezoelectric films 422, 424 have been formed, operations continue with an upper electrode 240 being formed on the upper surface of the alternating polarization piezoelectric film stack 420 (Block 365). The alternating polarization piezoelectric film stack 420 may also be etched and processed in the same manner as discussed above with respect to FIG. 5I. In a subsequent step, the sacrificial material 214 that is in the recess 212 is selectively removed so that the alternating polarization piezoelectric film stack 220 with the lower and upper electrodes 230, 240 on opposed surfaces thereof is suspended above the release bathtub (Block 370).

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of an acoustic wave resonator are considered to “vertically overlap” if an axis that is perpendicular to the major surfaces of a substrate of the acoustic wave resonator intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes,” “including” and “having” when used herein, specify the presence of stated features, elements, and/or components, but do not preclude the presence or addition of one or more other features, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical embodiments of the invention and, although specific terms are employed, they are used in a generic and descriptive sense only and not for purposes of limitation, the scope of the invention being set forth in the following claims.

1. A method of fabricating a bulk acoustic wave resonator, the method comprising:
forming a first metal-polar piezoelectric film on a substrate;
forming a first polarization inversion interlayer on the first metal-polar piezoelectric film via molecular beam epitaxy;
forming a first N-polar nucleation layer on the first polarization inversion interlayer; and
forming a first N-polar piezoelectric film on the first N-polar nucleation layer via molecular beam epitaxy.

2. The method of claim 1, further comprising:
forming a second polarization inversion interlayer on the first N-polar piezoelectric film via molecular beam epitaxy; and
forming a second metal-polar piezoelectric film on the second polarization inversion interlayer via molecular beam epitaxy.

3. The method of claim 2, further comprising forming a recess in the substrate and forming a sacrificial material in the recess prior to forming the first metal-polar piezoelectric film, wherein the first metal-polar piezoelectric film is also formed on the sacrificial material.

4. The method of claim 3, wherein the first metal-polar piezoelectric film comprises a first metal-polar scandium aluminum nitride film that is formed by molecular beam epitaxy.

5-9. (canceled)

10. The method of claim 1, wherein the first polarization inversion interlayer comprises silicon.

11. The method of claim 10, wherein the first N-polar nucleation layer comprises an N-polar aluminum nitride nucleation layer that is formed by molecular beam epitaxy in an aluminum rich growth condition.

12-13. (canceled)

14. The method of claim 1, wherein the first N-polar nucleation layer comprises a first N-polar aluminum nitride nucleation layer that is formed by molecular beam epitaxy and the first N-polar piezoelectric film comprises a first N-polar scandium aluminum nitride film that is formed by molecular beam epitaxy.

15. The method of claim 14, further comprising performing an anneal to burn-off excess aluminum after forming the N-polar aluminum nitride nucleation layer and before forming the first N-polar scandium aluminum nitride film.

16. (canceled)

17. The method of claim 2, wherein forming the second polarization inversion interlayer on the first N-polar piezoelectric film via molecular beam epitaxy comprises forming a second polarization inversion interlayer that comprises aluminum silicon nitride and/or aluminum oxide on the first N-polar piezoelectric film via molecular beam epitaxy.

18. (canceled)

19. A method of fabricating a bulk acoustic wave resonator, the method comprising:
forming a recess in a substrate;
forming a sacrificial material in the recess;
forming a lower electrode on substrate and the sacrificial material; and
forming an alternating polarization piezoelectric film stack that comprises at least two piezoelectric films using a molecular beam epitaxy system without removing the substrate from the molecular beam epitaxy system.

20. The method of claim 19, wherein the at least two piezoelectric films a first metal-polar piezoelectric film and a first N-polar piezoelectric film.

21. The method of claim 20, wherein forming a second metal-polar piezoelectric film on the second polarization inversion interlayer via molecular beam epitaxy comprises forming a metal-polar scandium aluminum nitride via molecular beam epitaxy.

22. The method of claim 19, wherein forming the alternating polarization piezoelectric film stack that comprises at least two piezoelectric films comprises forming an interlayer between a first of the at least two piezoelectric films and a second of the at least two piezoelectric films that is formed after the first of the at least two piezoelectric films is formed.

23. The method of claim 22, wherein forming the alternating polarization piezoelectric film stack that comprises at least two piezoelectric films further comprises forming a nucleation layer on the first of the at least two piezoelectric films before forming the second of the at least two piezoelectric films.

24-34. (canceled)

35. A method of fabricating a bulk acoustic wave resonator, the method comprising:
forming a first piezoelectric film on a substrate, the first piezoelectric film having a first polarization;
forming a first polarization inversion interlayer on the first piezoelectric film via molecular beam epitaxy;
forming a first nucleation layer on the first polarization inversion interlayer; and
forming a second piezoelectric film on the first nucleation layer via molecular beam epitaxy, the second piezoelectric film having a second polarization that is different than the first polarization.

36. The method of claim 35, further comprising:
forming a second polarization inversion interlayer on the second piezoelectric film via molecular beam epitaxy; and
forming a third piezoelectric film on the second polarization inversion interlayer via molecular beam epitaxy, the third piezoelectric film having the first polarization.

37. The method of claim 36, further comprising forming a recess in the substrate and forming a sacrificial material in the recess prior to forming the first piezoelectric film, wherein the first piezoelectric film is also formed on the sacrificial material.

38-39. (canceled)

40. The method of claim 37, further comprising, prior to forming the first piezoelectric film:
forming a lower electrode on the sacrificial material; and
forming a seed layer on the lower electrode.

41. The method of claim 40, wherein forming the seed layer on the lower electrode comprises sputtering an N-polar aluminum nitride layer on the lower electrode.

42. The method of claim 41, further comprising moving the substrate having the sacrificial material in the recess and the lower electrode and seed layer on the sacrificial material into a Molecular Beam Epitaxy growth chamber and performing an in-situ cleaning process thereon.
